(19) United States
(12) Patent Application Publication
(10) Pub. No.: US 2024/0304548 A1
(43) Pub. Date: Sep. 12, 2024

(54) SEMICONDUCTOR MEMORY DEVICE

(71) Applicant: Kioxia Corporation, Tokyo (JP)

(72) Inventors: Toru NAKANISHI, Yokohama Kanagawa (JP); Fumitaka ARAI, Yokohama Kanagawa (JP); Kouji MATSUO, Ama Aichi (JP)

(73) Assignee: Kioxia Corporation, Tokyo (JP)

(21) Appl. No.: 18/588,565

(22) Filed: Feb. 27, 2024

(30) Foreign Application Priority Data
Mar. 10, 2023 (JP) 2023-038100

(51) Int. Cl. H01L 23/528; H10B 41/10; H10B 41/27; H10B 41/35; H10B 43/10; H10B 43/27; H10B 43/35

(52) U.S. Cl. CPC H01L 23/5283; H10B 41/10; H10B 41/27; H10B 41/35; H10B 43/10; H10B 43/27; H10B 43/35

(57) ABSTRACT

A semiconductor memory device of the embodiment includes first to fourth gate electrode layers which extend in a first direction, a first semiconductor layer which extends in a second direction intersecting the first direction and is provided between the first gate electrode layer and the third gate electrode layer, and between the second gate electrode layer and the fourth gate electrode layer, a first wiring layer which extends in a third direction intersecting the first direction and the second direction and is electrically connected to the first gate electrode layer, a second wiring layer which is electrically connected to the second gate electrode layer, a third wiring layer which extends in the third direction and is electrically connected to the third gate electrode layer, and a fourth wiring layer which extends in the third direction and is electrically connected to the fourth gate electrode layer. The first wiring layer is provided between the third wiring layer and the fourth wiring layer, and the second wiring layer is provided between the first wiring layer and the fourth wiring layer.

### CROSS-REFERENCE TO RELATED APPLICATION

This application is based upon and claims the benefit of priority from Japanese Patent Application No. 2023-038100, filed Mar. 10, 2023, the entire contents of which are incorporated herein by reference.

### FIELD

Embodiments described herein relate generally to a semiconductor memory device.

### BACKGROUND

A three-dimensional NAND flash memory in which memory cells are arranged three-dimensionally realizes high integration and low cost. By miniaturizing the memory cells of the three-dimensional NAND flash memory, it is possible to further increase the integration.

### DESCRIPTION OF THE DRAWINGS

FIG. 1 is a pattern layout view of a semiconductor memory device of an embodiment.

FIG. 2 is a schematic sectional view of the semiconductor memory device of the embodiment.

FIG. 3 is a schematic sectional view of the semiconductor memory device of the embodiment.

FIG. 4 is a schematic sectional view of the semiconductor memory device of the embodiment.

FIG. 5 is a schematic sectional view of the semiconductor memory device of the embodiment.

FIG. 6 is a schematic sectional view of the semiconductor memory device of the embodiment.

FIG. 7 is a schematic sectional view of the semiconductor memory device of the embodiment.

FIG. 8 is a schematic sectional view of the semiconductor memory device of the embodiment.

FIG. 9 is a schematic sectional view showing a manufacturing method of the semiconductor memory device of the embodiment.

FIG. 10 is a schematic sectional view showing a manufacturing method of the semiconductor memory device of the embodiment.

FIG. 11 is a schematic sectional view showing the manufacturing method of the semiconductor memory device of the embodiment.

FIG. 12 is a schematic sectional view showing the manufacturing method of the semiconductor memory device of the embodiment.

FIG. 13 is a schematic sectional view showing the manufacturing method of the semiconductor memory device of the embodiment.

FIG. 14 is a schematic sectional view showing the manufacturing method of the semiconductor memory device of the embodiment.

FIG. 15 is a schematic sectional view showing the manufacturing method of the semiconductor memory device of the embodiment.

FIG. 16 is a schematic sectional view showing the manufacturing method of the semiconductor memory device of the embodiment.

FIG. 17 is a schematic sectional view showing the manufacturing method of the semiconductor memory device of the embodiment.

FIG. 18 is a schematic sectional view showing the manufacturing method of the semiconductor memory device of the embodiment.

FIG. 19 is a schematic sectional view showing the manufacturing method of the semiconductor memory device of the embodiment.

FIG. 20 is a schematic sectional view showing the manufacturing method of the semiconductor memory device of the embodiment.

FIG. 21 is a schematic sectional view showing the manufacturing method of the semiconductor memory device of the embodiment.

FIG. 22 is a schematic sectional view showing the manufacturing method of the semiconductor memory device of the embodiment.

FIG. 23 is a schematic sectional view showing the manufacturing method of the semiconductor memory device of the embodiment.

FIG. 24 is a pattern layout view of a semiconductor memory device of a comparative example.

FIG. 25 is a schematic sectional view of the semiconductor memory device of the comparative example.

FIG. 26 is a schematic sectional view of the semiconductor memory device of the comparative example.

FIG. 27 is a view illustrating an operation and an effect of the semiconductor memory device of the embodiment.

FIG. 28 is a view illustrating an operation and an effect of the semiconductor memory device of the embodiment.

FIG. 29 is a pattern layout view of a semiconductor memory device of a modification example of the embodiment.

### DETAILED DESCRIPTION

Embodiments provide a semiconductor memory device having improved characteristics.

In general, according to at least one embodiment, a semiconductor memory device of the embodiment includes: a first gate electrode layer which extends in a first direction; a second gate electrode layer which extends in the first direction and is provided in a second direction intersecting the first direction with respect to the first gate electrode layer; a third gate electrode layer which extends in the first direction and is provided in a third direction intersecting the first direction and the second direction with respect to the first gate electrode layer; a fourth gate electrode layer which extends in the first direction, is provided in the second direction with respect to the third gate electrode layer, and is provided in the third direction with respect to the second gate electrode layer; a first semiconductor layer which extends in the second direction and is provided between the first gate electrode layer and the third gate electrode layer, and between the second gate electrode layer and the fourth gate electrode layer; a first charge storage layer which is provided between the first gate electrode layer and the first semiconductor layer; a second charge storage layer which is provided between the second gate electrode layer and the first semiconductor layer; a third charge storage layer which is provided between the third gate electrode layer and the first semiconductor layer; a fourth charge storage layer which is provided between the fourth gate electrode layer and the first semiconductor layer; a first wiring layer which extends in the third direction and is electrically connected to the first gate electrode layer; a second wiring layer which extends in the third direction, is provided in the second direction with respect to the first wiring layer, and is electrically connected to the second gate electrode layer; a third wiring layer which extends in the third direction and is electrically connected to the third gate electrode layer; and a fourth wiring layer which extends in the third direction, is provided in the second direction with respect to the third wiring layer, and is electrically connected to the fourth gate electrode layer. The first wiring layer is provided between the third wiring layer and the fourth wiring layer, and the second wiring layer is provided between the first wiring layer and the fourth wiring layer.

Hereinafter, embodiments of the present disclosure will be described with reference to the drawings. In the following description, the same reference numerals are given to the same or similar members, and the description thereof will be omitted as appropriate. In addition, in the description, for elements with reference signs including English letters at the end for distinction, when it is not necessary to distinguish the elements from each other, a reference sign in which the English letter at the end is omitted may be used.

In addition, in the present specification, the term such as “upper” or “lower” may be used for convenience. “Upper” or “lower” is a term indicating, for example, a relative positional relationship in the drawings. The term “upper” or “lower” is not necessarily a term that define a positional relationship with respect to gravity.

The qualitative analysis and the quantitative analysis of the chemical composition of the members constituting the semiconductor memory device in the present specification may be performed by, for example, secondary ion mass spectrometry (SIMS) and energy dispersive X-ray spectroscopy (EDX). In addition, for the measurement of a thickness of the member constituting the semiconductor memory device, a distance between the members, and the like, for example, it is possible to use a transmission electron microscope (TEM).

The semiconductor memory device of the embodiment includes: a first gate electrode layer which extends in a first direction; a second gate electrode layer which extends in the first direction and is provided in a second direction intersecting the first direction with respect to the first gate electrode layer; a third gate electrode layer which extends in the first direction and is provided in a third direction intersecting the first direction and the second direction with respect to the first gate electrode layer; a fourth gate electrode layer which extends in the first direction, is provided in the second direction with respect to the third gate electrode layer, and is provided in the third direction with respect to the second gate electrode layer; a first semiconductor layer which extends in the second direction and is provided between the first gate electrode layer and the third gate electrode layer, and between the second gate electrode layer and the fourth gate electrode layer; a first charge storage layer which is provided between the first gate electrode layer and the first semiconductor layer; a second charge storage layer which is provided between the second gate electrode layer and the first semiconductor layer; a third charge storage layer which is provided between the third gate electrode layer and the first semiconductor layer; a fourth charge storage layer which is provided between the fourth gate electrode layer and the first semiconductor layer; a first wiring layer which extends in the third direction and is electrically connected to the first gate electrode layer; a second wiring layer which extends in the third direction, is provided in the second direction with respect to the first wiring layer, and is electrically connected to the second gate electrode layer; a third wiring layer which extends in the third direction and is electrically connected to the third gate electrode layer; and a fourth wiring layer which extends in the third direction, is provided in the second direction with respect to the third wiring layer, and is electrically connected to the fourth gate electrode layer. The first wiring layer is provided between the third wiring layer and the fourth wiring layer, and the second wiring layer is provided between the first wiring layer and the fourth wiring layer.

The semiconductor memory device of the embodiment is a three-dimensional NAND flash memory. In the semiconductor memory device of the embodiment, a plurality of semiconductor layers extending in a direction parallel to a surface of a semiconductor substrate are stacked on the semiconductor substrate. A memory cell is formed at an intersection portion between a gate electrode layer extending in a direction intersecting the surface of the semiconductor substrate and the semiconductor layer. The memory cell of the semiconductor memory device of the embodiment is a so-called floating gate type memory cell.

In the embodiment, the second direction is a direction intersecting the first direction. In addition, the third direction is a direction intersecting the first direction and the second direction. The second direction is, for example, a direction orthogonal to the first direction. In addition, the third direction is, for example, a direction orthogonal to the first direction and the second direction. Hereinafter, an x direction is an example of the third direction. A y direction is an example of the second direction. A z direction is an example of the first direction. The x direction, the y direction, and the z direction are directions orthogonal to each other.

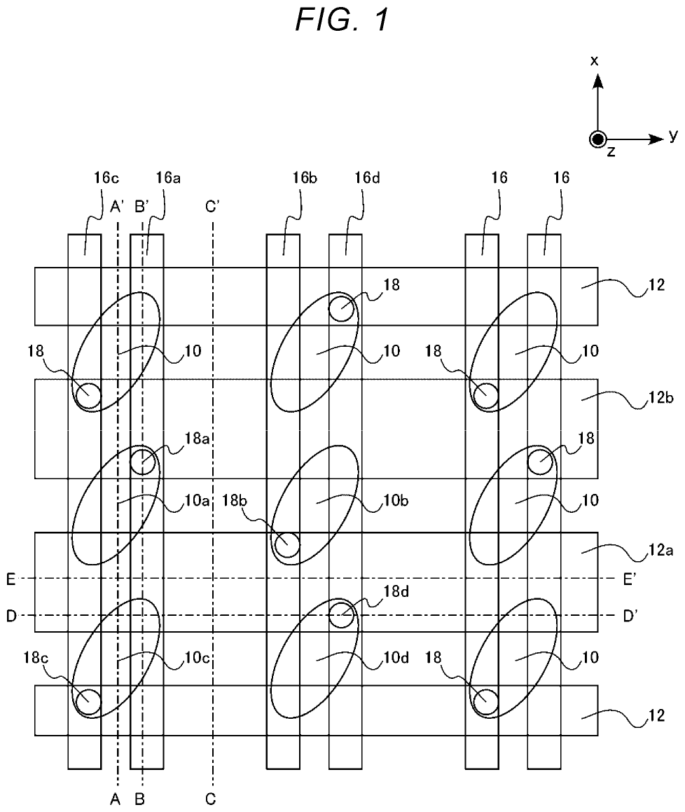

FIG. 1 is a pattern layout view of the semiconductor memory device of the embodiment. FIG. 1 shows a pattern layout of elements of a memory cell array of the three-dimensional NAND flash memory. FIG. 1 is a view in which patterns of each of the elements are projected on an xy plane.

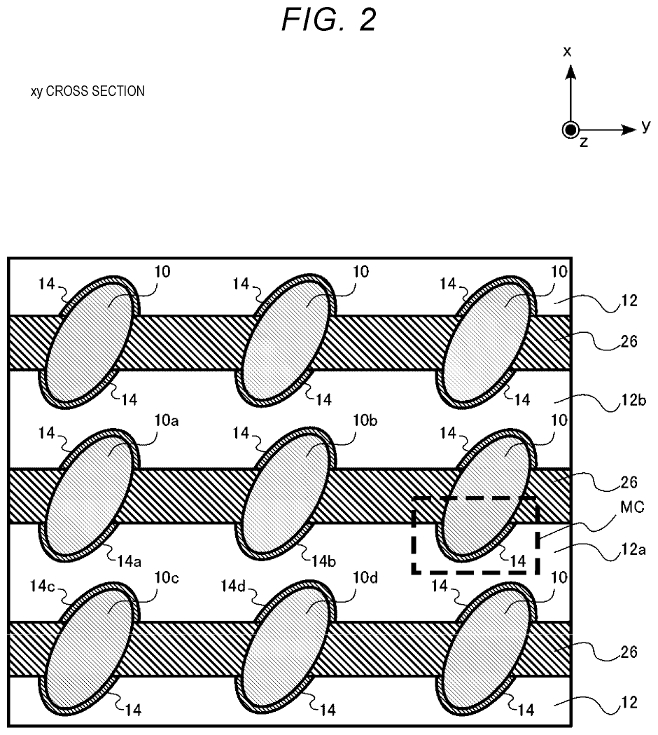

FIGS. 2 to 8 are schematic sectional views of the semiconductor memory device of the embodiment. FIGS. 2 to 8 are cross-sectional views of the memory cell array of the three-dimensional NAND flash memory of the embodiment.

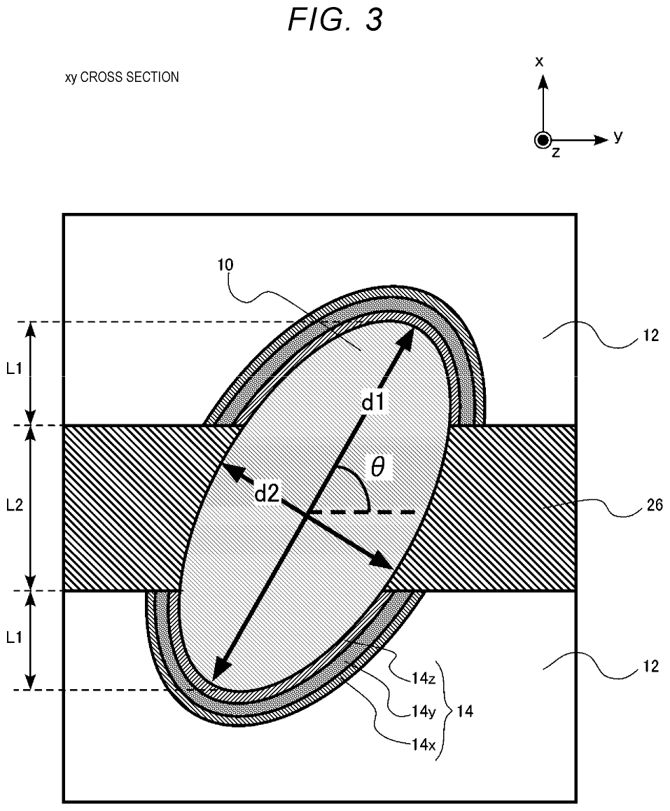

FIGS. 2 and 3 are xy cross-sectional views of the memory cell array. FIG. 3 is an enlarged view of a part of FIG. 2. FIGS. 2 and 3 are cross-sectional views including the semiconductor layer.

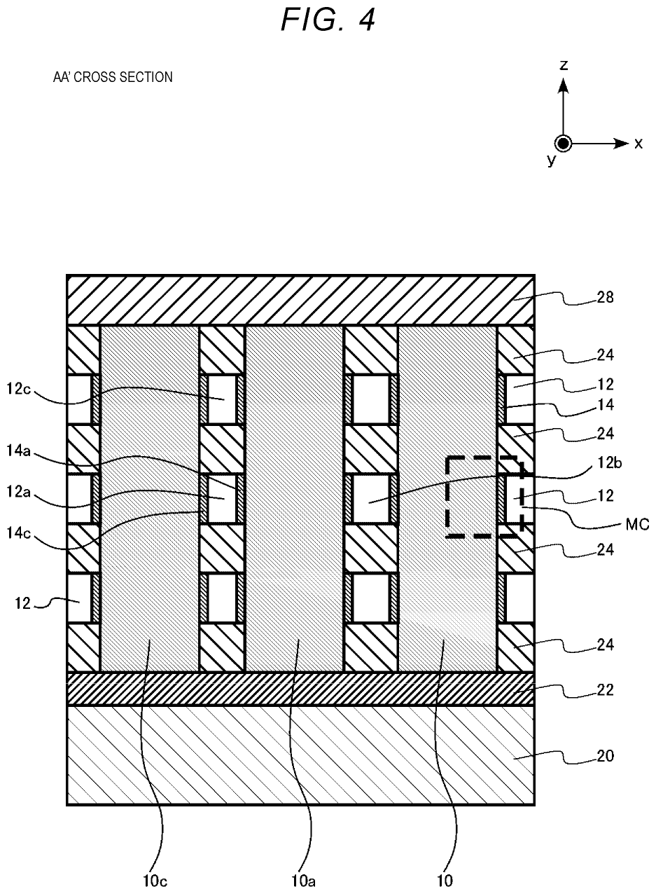

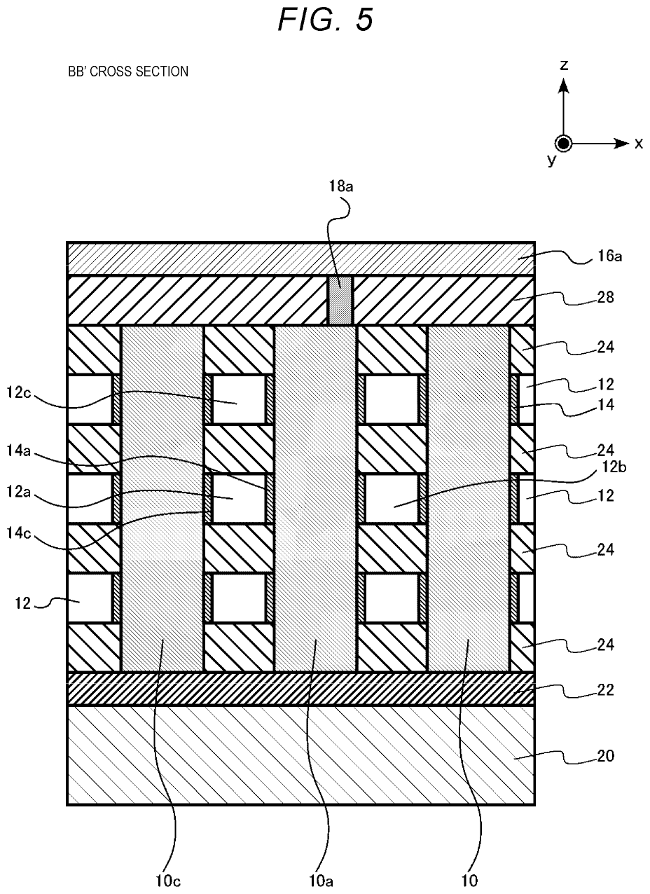

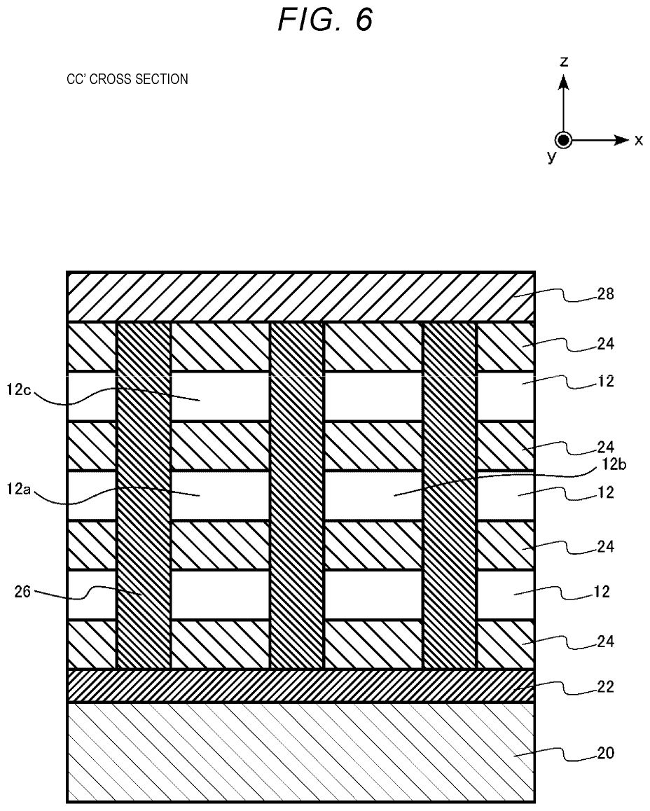

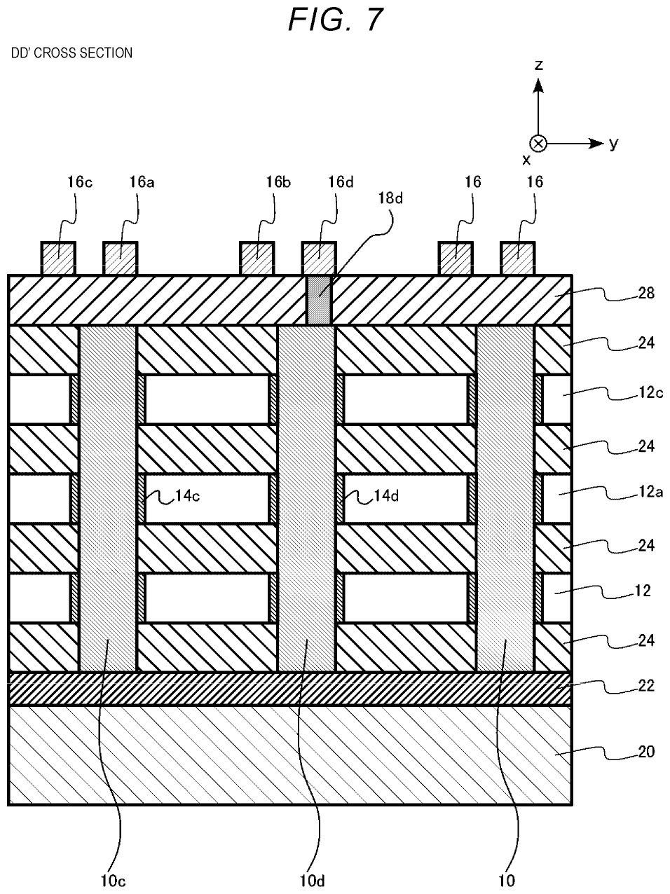

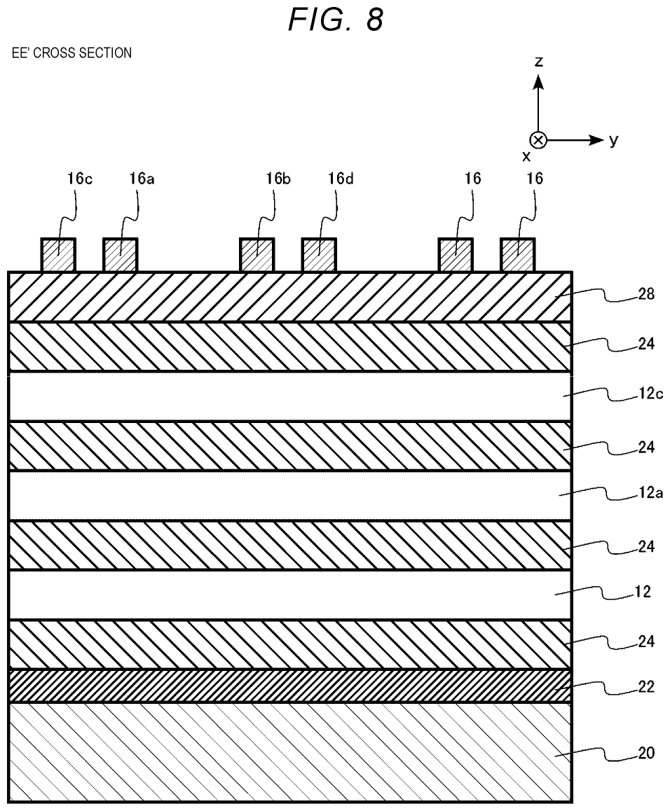

FIG. 4 is a cross-sectional view taken along the line AA′ of FIG. 1. FIG. 5 is a cross-sectional view taken along the line BB′ of FIG. 1. FIG. 6 is a cross-sectional view taken along the line CC′ of FIG. 1. FIG. 7 is a cross-sectional view taken along the line DD′ of FIG. 1. FIG. 8 is a cross-sectional view taken along the line EE′ of FIG. 1.

For example, a region surrounded by the broken line in FIGS. 2 and 4 is one memory cell MC.

The three-dimensional NAND flash memory of the embodiment includes, for example, a peripheral circuit (not shown). The peripheral circuit is configured with, for example, a CMOS circuit and has a function of controlling the operation of the memory cell array.

The three-dimensional NAND flash memory of the embodiment includes a plurality of gate electrode layers 10, a plurality of semiconductor layers 12, a plurality of charge storage layers 14, a plurality of gate wiring layers 16, and a plurality of contact plugs 18. In addition, the three-dimensional NAND flash memory of the embodiment includes a semiconductor substrate 20, a substrate insulating layer 22, a first interlayer insulating layer 24, a second interlayer insulating layer 26, and a third interlayer insulating layer 28.

The plurality of gate electrode layers 10 include a first gate electrode layer 10a, a second gate electrode layer 10b, a third gate electrode layer 10c, and a fourth gate electrode layer 10d. The plurality of semiconductor layers 12 include a first semiconductor layer 12a, a second semiconductor layer 12b, and a third semiconductor layer 12c. The plurality of charge storage layers 14 include a first charge storage layer 14a, a second charge storage layer 14b, a third charge storage layer 14c, and a fourth charge storage layer 14d. The plurality of gate wiring layers 16 include a first gate wiring layer 16a, a second gate wiring layer 16b, a third gate wiring layer 16c, and a fourth gate wiring layer 16d. The plurality of contact plugs 18 include a first contact plug 18a, a second contact plug 18b, a third contact plug 18c, and a fourth contact plug 18d.

The first gate wiring layer 16a, the second gate wiring layer 16b, the third gate wiring layer 16c, and the fourth gate wiring layer 16d are examples of a first wiring layer, a second wiring layer, a third wiring layer, and a fourth wiring layer, respectively. The first contact plug 18a, the second contact plug 18b, the third contact plug 18c, and the fourth contact plug 18d are examples of a first connection portion, a second connection portion, a third connection portion, and a fourth connection portion, respectively.

The semiconductor substrate 20 is an example of a substrate.

The semiconductor substrate 20 is, for example, single crystal silicon. The semiconductor substrate 20 is, for example, a silicon substrate. The semiconductor substrate 20 has a surface parallel to the x direction and the y direction. The direction perpendicular to the surface of the semiconductor substrate 20 is the z direction.

The substrate insulating layer 22 is provided on the semiconductor substrate 20. The substrate insulating layer 22 includes, for example, silicon oxide or aluminum oxide. The substrate insulating layer 22 is, for example, a silicon oxide layer or an aluminum oxide layer.

The gate electrode layer 10 extends in the z direction intersecting a surface of the semiconductor substrate 20. The gate electrode layer 10 extends in the z direction perpendicular to the surface of the semiconductor substrate 20.

The second gate electrode layer 10b is provided in the y direction with respect to the first gate electrode layer 10a. The third gate electrode layer 10c is provided in the x direction with respect to the first gate electrode layer. The fourth gate electrode layer 10d is provided in the y direction with respect to the third gate electrode layer 10c. The fourth gate electrode layer 10d is provided in the x direction with respect to the second gate electrode layer 10b.

The gate electrode layer 10 has, for example, a major axis (d1 in FIG. 3c) and a minor axis (d2 in FIG. 3) shorter than the major axis in a cross section perpendicular to the z direction. In the cross section of the gate electrode layer 10 perpendicular to the z direction, when the gate electrode layer 10 is sandwiched between two parallel lines, a distance when the distance between the parallel lines is the largest is defined as the major axis, and a distance when the distance between the parallel lines is the smallest is defined as the minor axis.

In the cross section perpendicular to the z direction, the gate electrode layer 10 is, for example, elliptical.

In the cross section perpendicular to the z direction, a direction of the major axis of the gate electrode layer 10 and the x direction intersect each other. In the cross section perpendicular to the z direction, an angle (0 in FIG. 3) between the direction of the major axis of the gate electrode layer 10 and the y direction is less than 90 degrees. In the cross section perpendicular to the z direction, the angle (0 in FIG. 3) between the direction of the major axis of the gate electrode layer 10 and the y direction is, for example, 45 degrees or more and 75 degrees or less.

As shown in FIG. 3, in the cross section perpendicular to the z direction, a part of the gate electrode layer 10 enters the semiconductor layer 12. The channel length of the memory cell transistor of the memory cell MC controlled by the gate electrode layer 10 changes depending on the size of the entering amount of the gate electrode layer 10 into the semiconductor layer 12 in the x direction (L1 in FIG. 3). As the amount of gouging L1 increases, the channel length of the memory cell transistor increases, and for example, the cutoff characteristics of the transistor are improved.

The gate electrode layer 10 functions as a gate electrode of the memory cell transistor of the memory cell MC.

The gate electrode layer 10 is a columnar conductor. The gate electrode layer 10 includes, for example, a metal.

The gate electrode layer 10 includes, for example, tungsten (W). The gate electrode layer 10 is, for example, a tungsten layer.

The semiconductor layer 12 is provided on the substrate insulating layer 22. The semiconductor layer 12 extends in a direction along the surface of the semiconductor substrate 20. The semiconductor layer 12 extends in the y direction parallel to the surface of the semiconductor substrate 20.

The semiconductor layer 12 is repeatedly arranged in the z direction. The semiconductor layer 12 is repeatedly arranged in the x direction.

The second semiconductor layer 12b is provided in the x direction with respect to the first semiconductor layer 12a. The third semiconductor layer 12c is provided in the z direction with respect to the first semiconductor layer 12a.

The first semiconductor layer 12a is provided between the first gate electrode layer 10a and the third gate electrode layer 10c. The first semiconductor layer 12a is provided between the second gate electrode layer 10b and the fourth gate electrode layer 10d.

The first gate electrode layer 10a and the second gate electrode layer 10b are provided between the first semiconductor layer 12a and the second semiconductor layer 12b.

The third semiconductor layer 12c is provided between the first gate electrode layer 10a and the third gate electrode layer 10c. The third semiconductor layer 12c is provided between the second gate electrode layer 10b and the fourth gate electrode layer 10d.

The semiconductor layer 12 functions as a channel of the memory cell transistor of the memory cell MC.

The semiconductor layer 12 is, for example, a polycrystalline semiconductor. The semiconductor layer 12 includes, for example, polycrystalline silicon. The semiconductor layer 12 is, for example, a polycrystalline silicon layer. A thickness of the semiconductor layer 12 in the z direction is, for example, 5 nm or more and 30 nm or less.

The charge storage layer 14 is provided between the gate electrode layer 10 and the semiconductor layer 12. The first charge storage layer 14a is provided between the first gate electrode layer 10a and the first semiconductor layer 12a. The second charge storage layer 14b is provided between the second gate electrode layer 10b and the first semiconductor layer 12a. The third charge storage layer 14c is provided between the third gate electrode layer 10c and the first semiconductor layer 12a. The fourth charge storage layer 14d is provided between the fourth gate electrode layer 10d and the first semiconductor layer 12a.

As shown in FIG. 3, the charge storage layer 14 includes a tunnel insulating film 14x, a charge storage area 14y, and a block insulating film 14z.

The tunnel insulating film 14x is provided between the semiconductor layer 12 and the gate electrode layer 10. The tunnel insulating film 14x is provided between the semiconductor layer 12 and the charge storage area 14y. The tunnel insulating film 14x is in contact with the semiconductor layer 12. The tunnel insulating film 14x is in contact with the charge storage area 14y.

The tunnel insulating film 14x has a function of allowing charge to pass according to a voltage applied between the gate electrode layer 10 and the semiconductor layer 12.

The tunnel insulating film 14x contains, for example, silicon oxide, silicon nitride, or silicon oxynitride. The tunnel insulating film 14x is, for example, a silicon oxide film. The tunnel insulating film 14x is, for example, a thermal oxide film of silicon.

The charge storage area 14y is provided between the tunnel insulating film 14x and the gate electrode layer 10. The charge storage area 14y is provided between the tunnel insulating film 14x and the block insulating film 14z. The charge storage area 14y is in contact with the tunnel insulating film 14x. The charge storage area 14y is in contact with the block insulating film 14z.

The charge storage area 14y has a function of storing charge. The charge is, for example, an electron. The threshold voltage of the memory cell transistor changes according to the amount of charge stored in the charge storage area 14y. By using the change in the threshold voltage, one memory cell MC is capable of storing data. When the amount of charge stored in the charge storage area 14y increases, the amount of change in the threshold voltage increases.

For example, the threshold voltage of the memory cell transistor is changed, so that the voltage at which the memory cell transistor is turned on is changed. For example, when a state in which the threshold voltage is high is defined as data “0” and a state in which the threshold voltage is low is defined as data “1”, the memory cell is capable of storing 1-bit data of “0” and “1”.

The charge storage area 14y is, for example, a conductor. The charge storage area 14y includes, for example, polycrystalline silicon. The charge storage area 14y is, for example, a polycrystalline silicon layer.

The block insulating film 14z is provided between the charge storage area 14y and the gate electrode layer 10. The block insulating film 14z is in contact with the charge storage area 14y. The block insulating film 14z is in contact with the gate electrode layer 10.

The block insulating film 14z has a function of blocking a current flowing between the charge storage area 14y and the gate electrode layer 10.

The block insulating film 14z is, for example, an oxide, an oxynitride, or a nitride. The block insulating film 14z contains, for example, silicon oxide or aluminum oxide. The block insulating film 14z is, for example, a silicon oxide film or an aluminum oxide film. The block insulating film 14z is, for example, a stacked film of a silicon oxide film and an aluminum oxide film.

The gate wiring layer 16 is provided on the gate electrode layer 10. The gate wiring layer 16 extends in the direction along the surface of the semiconductor substrate 20. The gate wiring layer 16 extends in the x direction parallel to the surface of the semiconductor substrate 20.

The gate wiring layer 16 is repeatedly arranged in the y direction. The gate wiring layer 16 is electrically connected to the gate electrode layer 10.

The first gate wiring layer 16a is electrically connected to the first gate electrode layer 10a. The second gate wiring layer 16b is electrically connected to the second gate electrode layer 10b. The third gate wiring layer 16c is electrically connected to the third gate electrode layer 10c. The fourth gate wiring layer 16d is electrically connected to the fourth gate electrode layer 10d.

The third gate wiring layer 16c, the first gate wiring layer 16a, the second gate wiring layer 16b, and the fourth gate wiring layer 16d are arranged in this order in the y direction. The second gate wiring layer 16b is provided in the y direction with respect to the first gate wiring layer 16a. The fourth gate wiring layer 16d is provided in the y direction with respect to the first gate wiring layer 16a, the second gate wiring layer 16b, and the third gate wiring layer 16c.

The first gate wiring layer 16a is provided between the third gate wiring layer 16c and the fourth gate wiring layer 16d. The second gate wiring layer 16b is provided between the first gate wiring layer 16a and the fourth gate wiring layer 16d.

The gate wiring layer 16 has a function of applying the voltage to the gate electrode layer 10 which is electrically connected to the gate wiring layer 16.

The gate wiring layer 16 is a conductor. The gate wiring layer 16 includes, for example, a metal.

The gate wiring layer 16 includes, for example, tungsten (W), aluminum (Al), or copper (Cu). The gate electrode layer 10 is, for example, a tungsten layer, an aluminum layer, or a copper layer.

The contact plug 18 is provided between the gate electrode layer 10 and the gate wiring layer 16. The contact plug 18 physically and electrically connects the gate electrode layer 10 and the gate wiring layer 16, for example.

As shown in the pattern layout view of FIG. 1, the contact plug 18 is provided, for example, at an intersection portion between the gate electrode layer 10 and the gate wiring layer 16. As shown in FIG. 1, the contact plug 18 is provided, for example, at a position deviated from the center of gravity of the shape of the gate electrode layer 10 in the xy plane.

The first contact plug 18a is provided between the first gate electrode layer 10a and the first gate wiring layer 16a. The first contact plug 18a connects the first gate electrode layer 10a and the first gate wiring layer 16a.

The second contact plug 18b is provided between the second gate electrode layer 10b and the second gate wiring layer 16b. The second contact plug 18b connects the second gate electrode layer 10b and the second gate wiring layer 16b.

The third contact plug 18c is provided between the third gate electrode layer 10c and the third gate wiring layer 16c. The third contact plug 18c connects the third gate electrode layer 10c and the third gate wiring layer 16c.

The fourth contact plug 18d is provided between the fourth gate electrode layer 10d and the fourth gate wiring layer 16d. The fourth contact plug 18d connects the fourth gate electrode layer 10d and the fourth gate wiring layer 16d.

A direction in which the first contact plug 18a and the second contact plug 18b are connected intersects the y direction. In addition, a direction in which the third contact plug 18c and the fourth contact plug 18d are connected intersects the y direction. A direction in which the first contact plug 18a and the second contact plug 18b are connected intersects, for example, a direction in which the third contact plug 18c and the fourth contact plug 18d are connected.

The contact plug 18 is a conductor. The contact plug 18 includes, for example, a metal.

The contact plug 18 includes, for example, tungsten (W), aluminum (Al), or copper (Cu). The contact plug 18 is, for example, a tungsten layer, an aluminum layer, or a copper layer.

The first interlayer insulating layer 24 is provided between two semiconductor layers 12 adjacent to each other in the z direction. The first interlayer insulating layer 24 is repeatedly arranged in the z direction.

The first interlayer insulating layer 24 has a function of electrically separating the two semiconductor layers 12 adjacent to each other in the z direction.

The first interlayer insulating layer 24 is, for example, an oxide, an oxynitride, or a nitride. The first interlayer insulating layer 24 contains, for example, silicon oxide. The first interlayer insulating layer 24 is, for example, a silicon oxide layer. A thickness of the first interlayer insulating layer 24 in the z direction is, for example, 5 nm or more and 50 nm or less.

The second interlayer insulating layer 26 is provided between the two semiconductor layers 12 adjacent to each other in the x direction. The second interlayer insulating layer 26 is repeatedly arranged in the x direction.

The second interlayer insulating layer 26 has a function of electrically separating the two semiconductor layers 12 adjacent to each other in the x direction.

The second interlayer insulating layer 26 is, for example, an oxide, an oxynitride, or a nitride. The second interlayer insulating layer 26 is formed of, for example, the same material as the first interlayer insulating layer 24.

The second interlayer insulating layer 26 is, for example, an oxide, an oxynitride, or a nitride. The second interlayer insulating layer 26 contains, for example, silicon oxide. The second interlayer insulating layer 26 is, for example, a silicon oxide layer.

The third interlayer insulating layer 28 is provided between the gate electrode layer 10 and the gate wiring layer 16. The third interlayer insulating layer 28 has a function of electrically separating the gate electrode layer 10 and the gate wiring layer 16.

The third interlayer insulating layer 28 is, for example, an oxide, an oxynitride, or a nitride. The third interlayer insulating layer 28 is formed of, for example, the same material as the first interlayer insulating layer 24 or as the second interlayer insulating layer 26.

The third interlayer insulating layer 28 is, for example, an oxide, an oxynitride, or a nitride. The third interlayer insulating layer 28 contains, for example, silicon oxide. The third interlayer insulating layer 28 is, for example, a silicon oxide layer.

The contact plug 18 is provided in the third interlayer insulating layer 28. The contact plug 18 penetrates the third interlayer insulating layer 28.

Next, an example of a manufacturing method of the semiconductor memory device of the embodiment will be described.

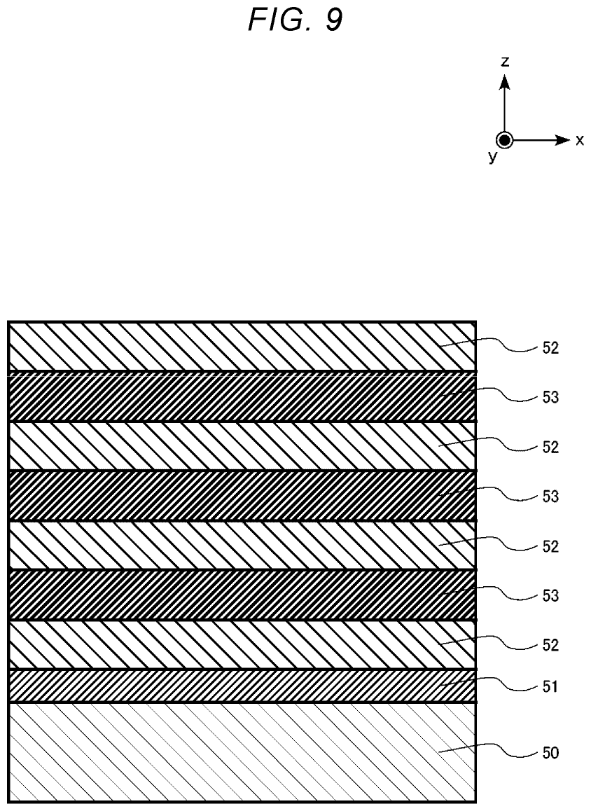

FIGS. 9 to 23 are schematic sectional views showing the manufacturing method of the semiconductor memory device of the embodiment. FIGS. 9 to 23 show cross sections corresponding to FIG. 4.

First, an aluminum oxide layer 51 is formed on a silicon substrate 50. The aluminum oxide layer 51 is formed by, for example, a chemical vapor deposition method (CVD method). The aluminum oxide layer 51 finally becomes the substrate insulating layer 22.

Next, a plurality of silicon oxide layers 52 and a plurality of silicon nitride layers 53 are alternately stacked on the aluminum oxide layer 51 (FIG. 9).

The silicon oxide layer 52 and the silicon nitride layer 53 are formed by, for example, the CVD method.

A part of the silicon oxide layer 52 finally becomes the first interlayer insulating layer 24. The silicon nitride layer 53 is finally substituted with amorphous silicon and becomes the semiconductor layer 12.

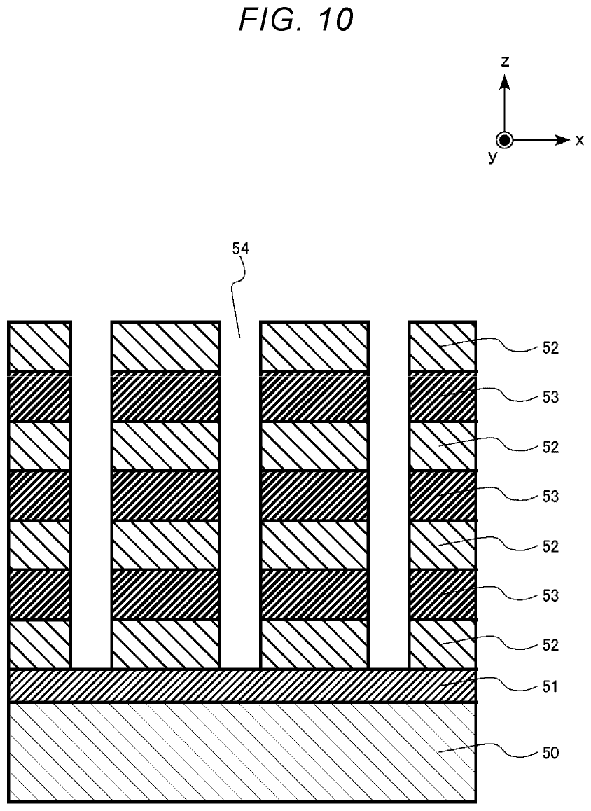

Next, a first opening 54 that penetrates the silicon oxide layer 52 and the silicon nitride layer 53 is formed (FIG. 10). The first opening 54 is formed by, for example, a lithography method and a reactive ion etching method (RIE method). The first opening 54 extends in the y direction. The first opening 54 is a separation area of the semiconductor layer 12.

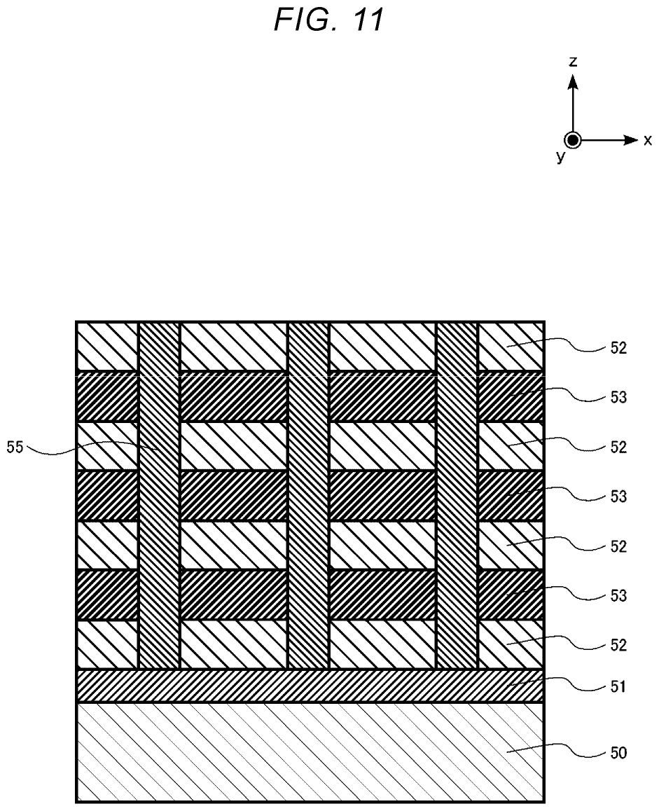

Next, the inside of the first opening 54 is filled with a first silicon oxide film 55 (FIG. 11). The first silicon oxide film 55 is formed by, for example, the CVD method. A part of the first silicon oxide film 55 finally becomes the second interlayer insulating layer 26.

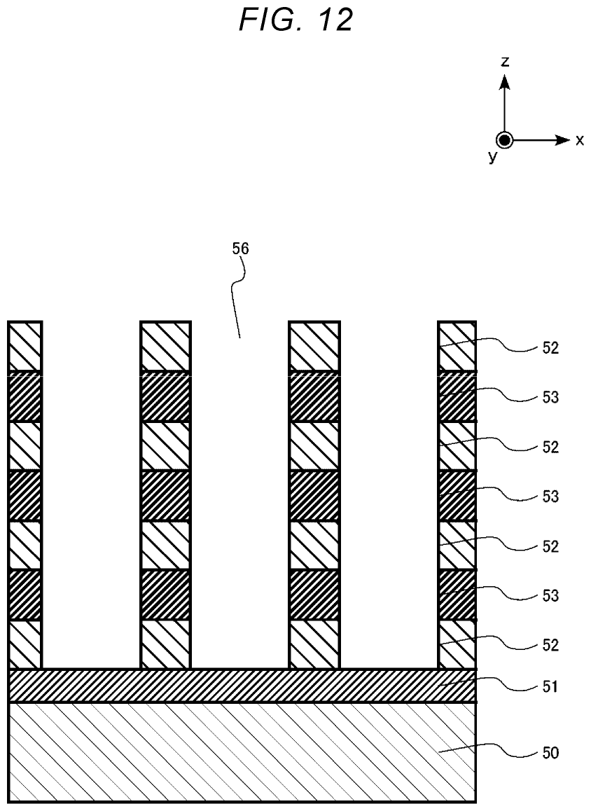

Next, a second opening 56 that penetrates the silicon oxide layer 52, the silicon nitride layer 53, and the first silicon oxide film 55 is formed (FIG. 12). The second opening 56 is formed by, for example, the lithography method and the RIE method. The second opening 56 is, for example, elliptical in the xy cross section. The second opening 56 is an area in which the gate electrode layer 10 is formed.

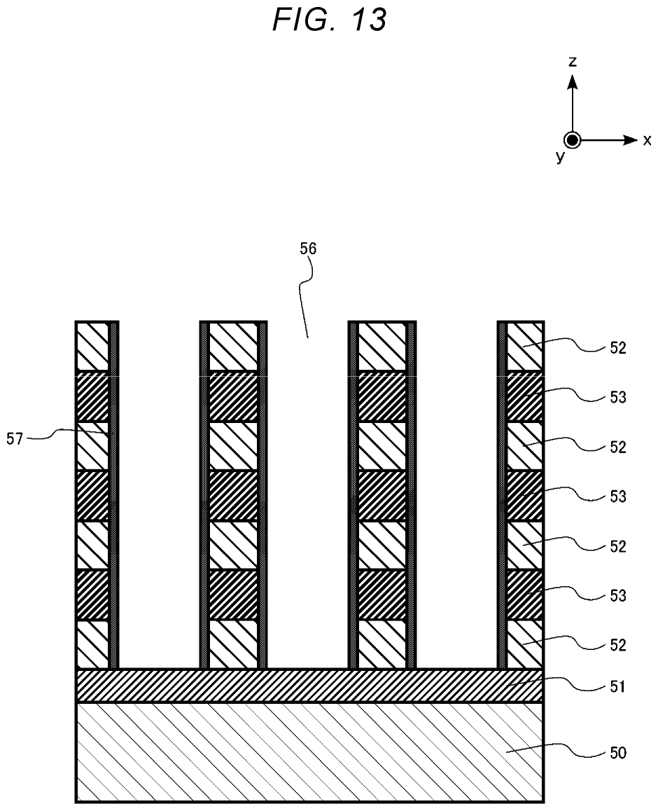

Next, a second silicon oxide film 57 is formed on an inner wall of the second opening 56 (FIG. 13). The second silicon oxide film 57 is formed by, for example, the CVD method.

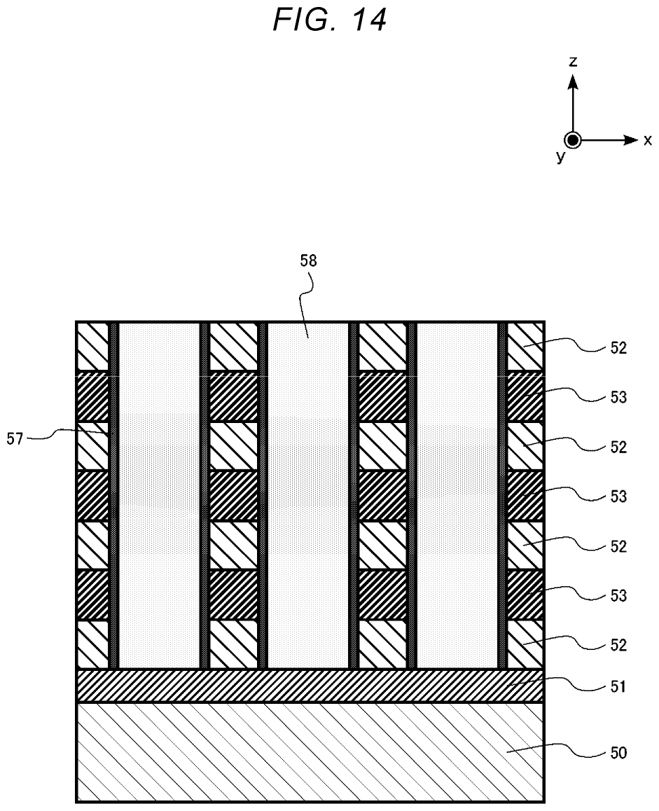

Next, the inside of the second opening 56 is filled with a first amorphous silicon film 58 (FIG. 14). The first amorphous silicon film 58 is formed by, for example, the CVD method. The first amorphous silicon film 58 is a sacrificial film for forming the gate electrode layer 10.

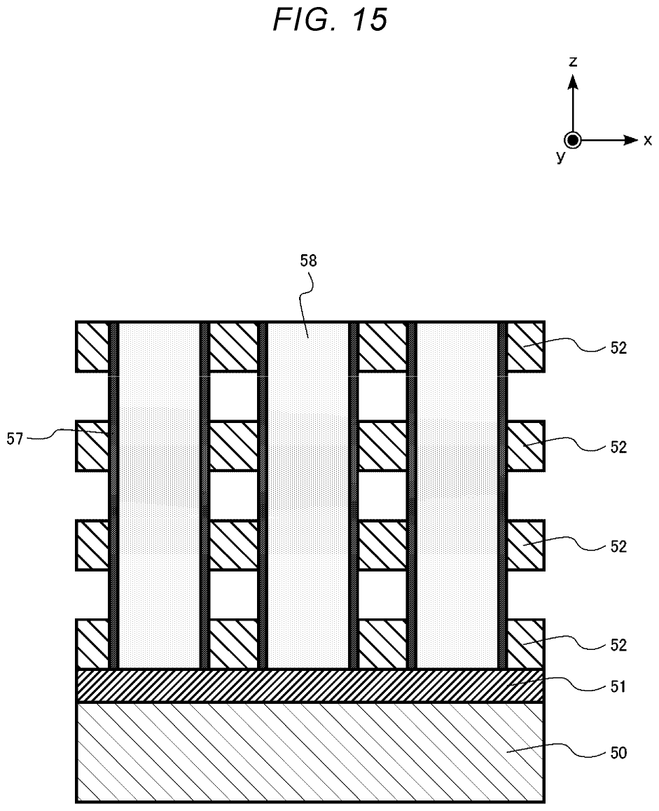

Next, the silicon nitride layer 53 is removed (FIG. 15). The silicon nitride layer 53 is removed by a wet etching method after, for example, forming an opening (not shown).

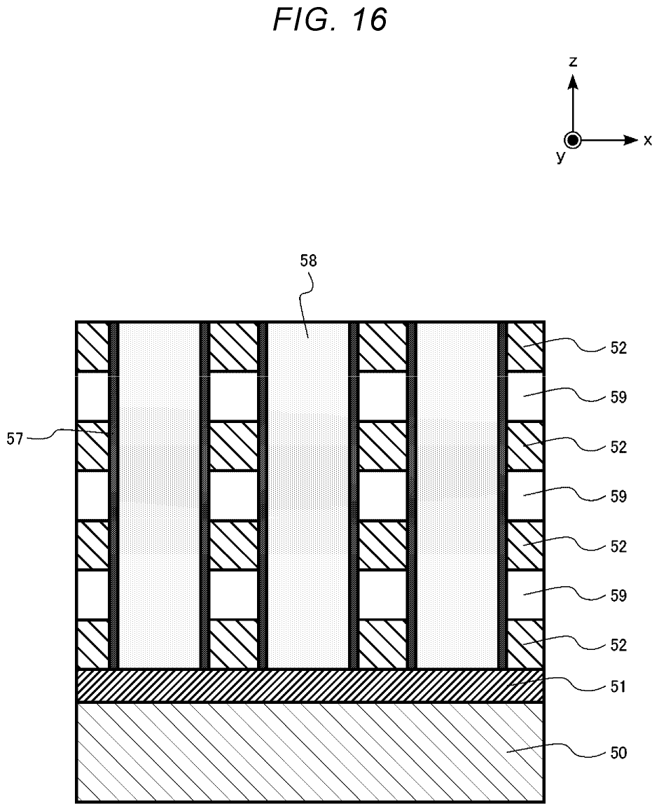

Next, the region from which the silicon nitride layer 53 is removed is filled with a second amorphous silicon film 59 (FIG. 16). The second amorphous silicon film 59 is formed by, for example, the CVD method. A part of the second amorphous silicon film 59 finally becomes the semiconductor layer 12.

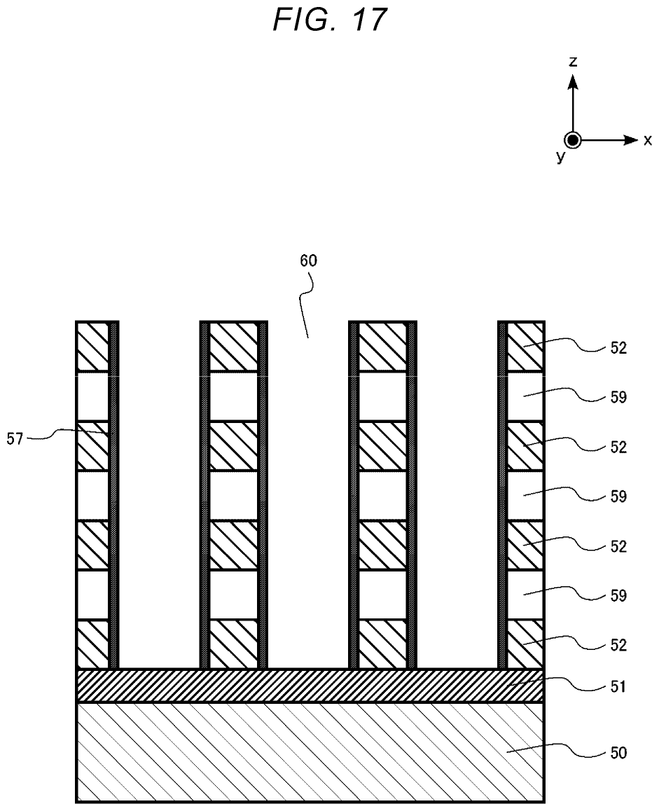

Next, the first amorphous silicon film 58 is removed to form a third opening 60 (FIG. 17). The first amorphous silicon film 58 is removed using, for example, the wet etching method.

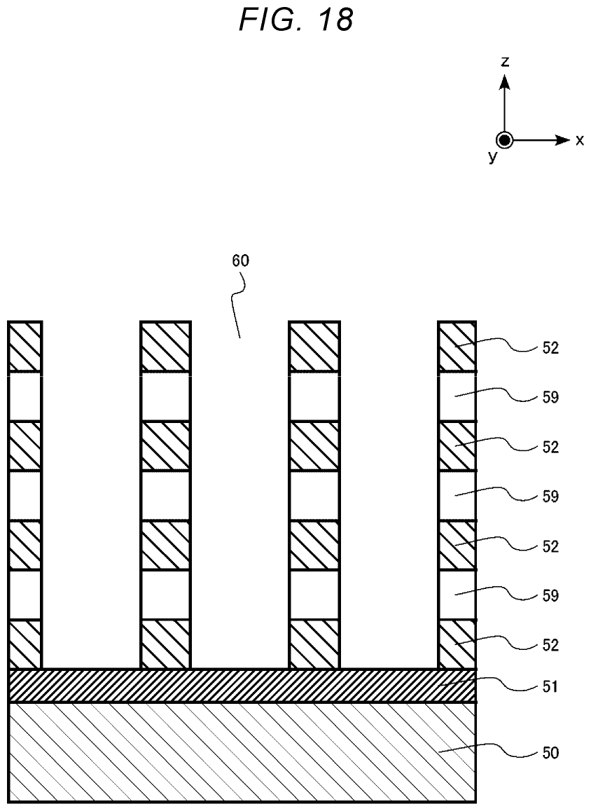

Next, the second silicon oxide film 57 on an inner wall of the third opening 60 is removed (FIG. 18). The second silicon oxide film 57 is removed using, for example, the wet etching method.

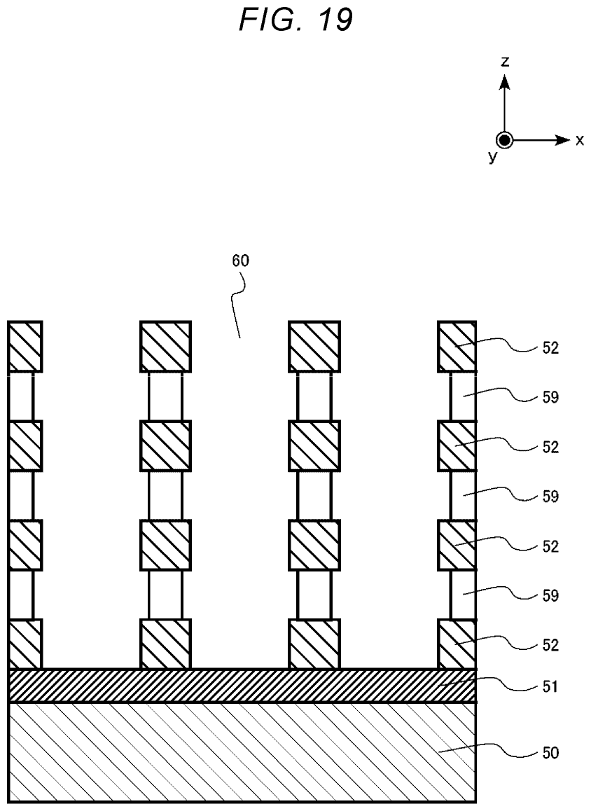

Next, the second amorphous silicon film 59 is retreated to the side from the inner wall of the third opening 60 (FIG. 19). The second amorphous silicon film 59 is etched using, for example, an isotropic dry etching method. The recessed portion of the second amorphous silicon film 59 is formed on the inner wall side of the third opening 60.

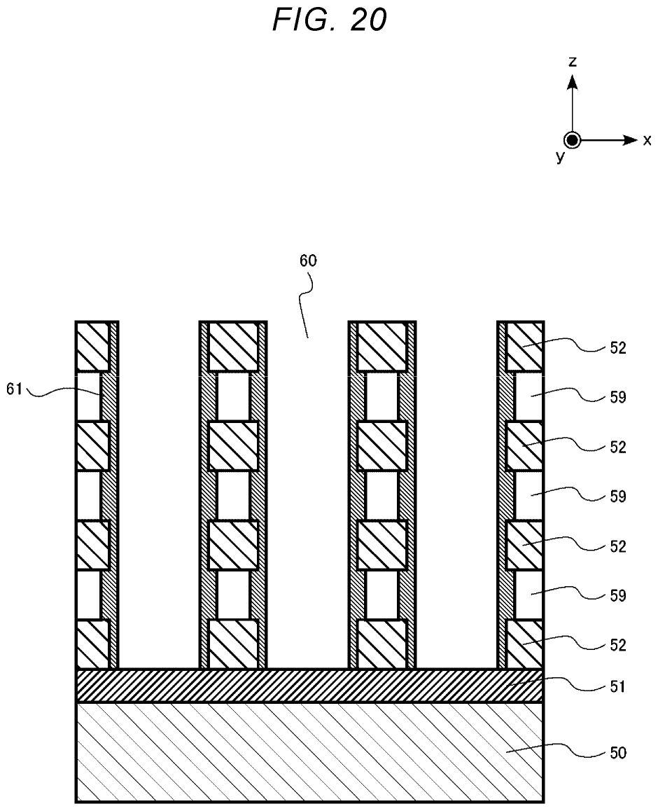

Next, the stacked film 61 is formed on the inner wall of the third opening 60 (FIG. 20). The stacked film 61 is, for example, a stacked film of a silicon oxide film, an amorphous silicon film, and a silicon oxide film. The stacked film 61 is formed using, for example, the CVD method. A part of the stacked film 61 finally becomes the charge storage layer 14.

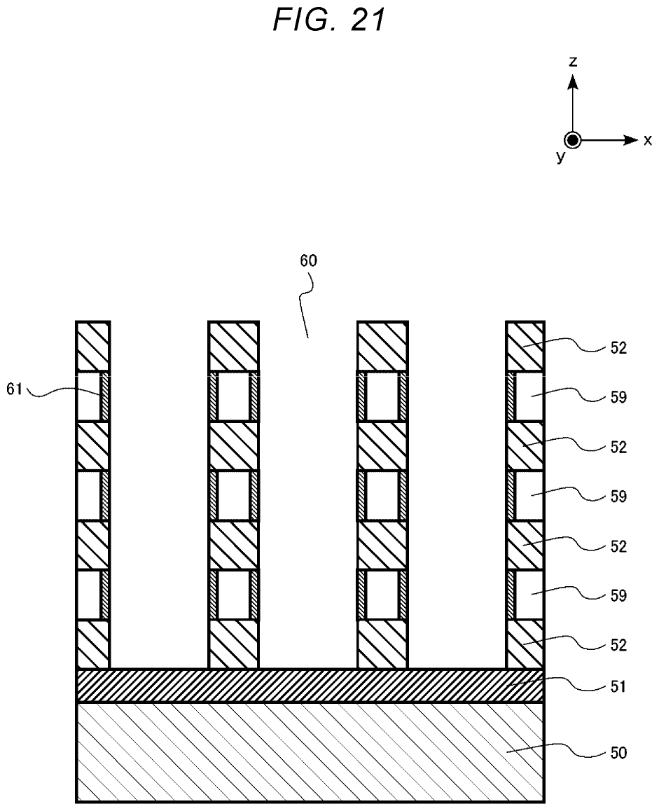

Next, a part of the stacked film 61 is etched, and the stacked film 61 is left only in the recessed portion of the second amorphous silicon film 59 (FIG. 21). The etching of the stacked film 61 is performed by, for example, the RIE method.

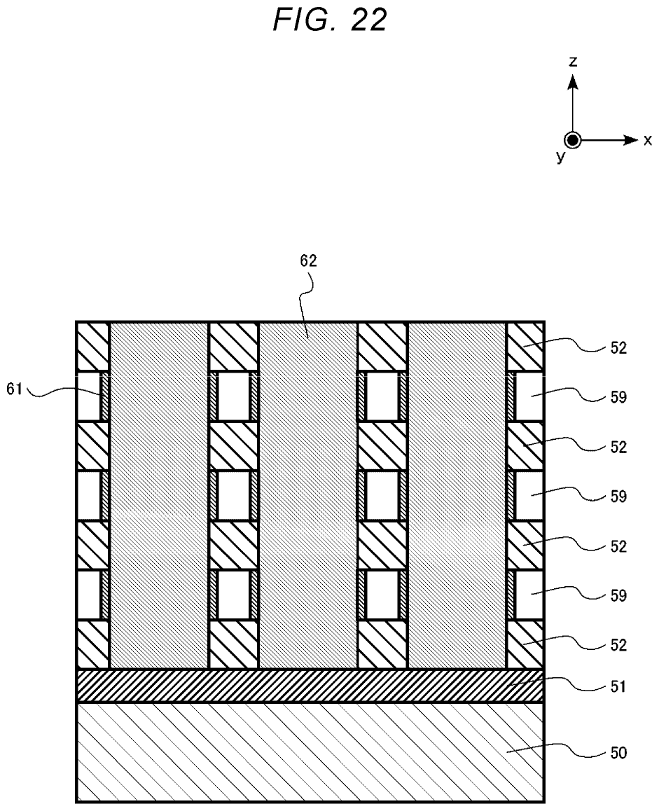

The inside of the third opening 60 is filled with a tungsten film 62 (FIG. 22). The tungsten film 62 is formed by, for example, the CVD method. The tungsten film 62 finally becomes the gate electrode layer 10.

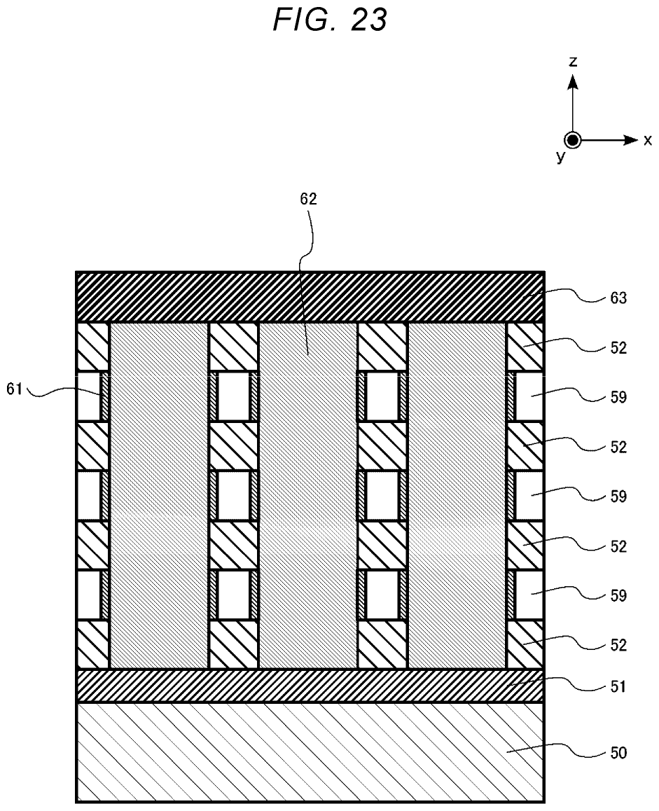

Next, a third silicon oxide film 63 is formed on the tungsten film 62 (FIG. 23). The third silicon oxide film 63 is formed by, for example, the CVD method. A part of the third silicon oxide film 63 finally becomes the third interlayer insulating layer 28.

Thereafter, the contact plug 18 and the gate wiring layer 16 are formed using a known process technology.

The three-dimensional NAND flash memory of the embodiment is manufactured by the above-described manufacturing method.

Next, an operation and an effect of the semiconductor memory device of the embodiment will be described.

A three-dimensional NAND flash memory in which memory cells are arranged three-dimensionally realizes high integration and low cost. By miniaturizing the memory cells of the three-dimensional NAND flash memory, it is possible to further increase the integration.

When the memory cell is miniaturized, for example, an interval between the wirings provided in the memory cell array is narrowed, and thus the wiring capacitance increases. When the wiring capacitance increases, an operation speed of the three-dimensional NAND flash memory decreases, for example.

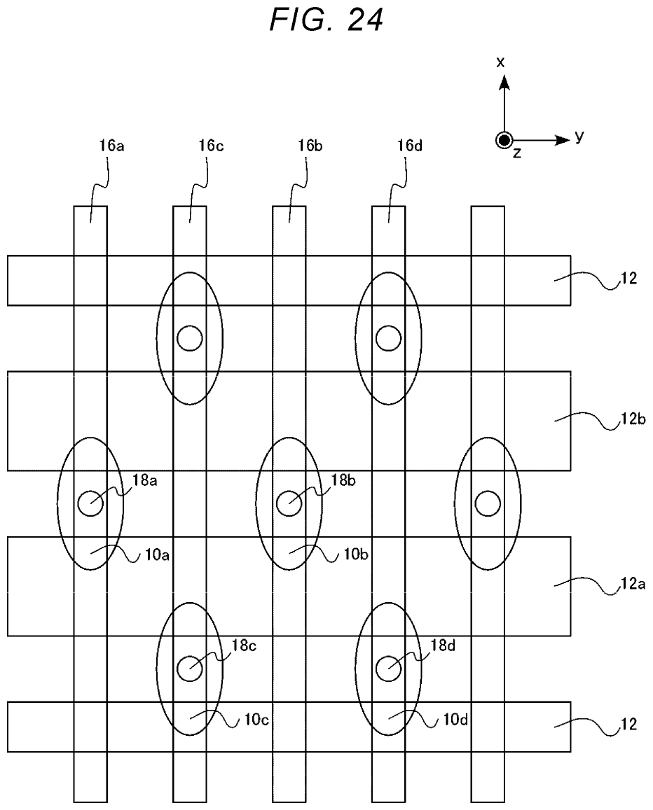

FIG. 24 is a pattern layout view of a semiconductor memory device of a comparative example. FIG. 24 is a view corresponding to FIG. 1 of the embodiment.

The semiconductor memory device of the comparative example is a three-dimensional NAND flash memory as in the embodiment.

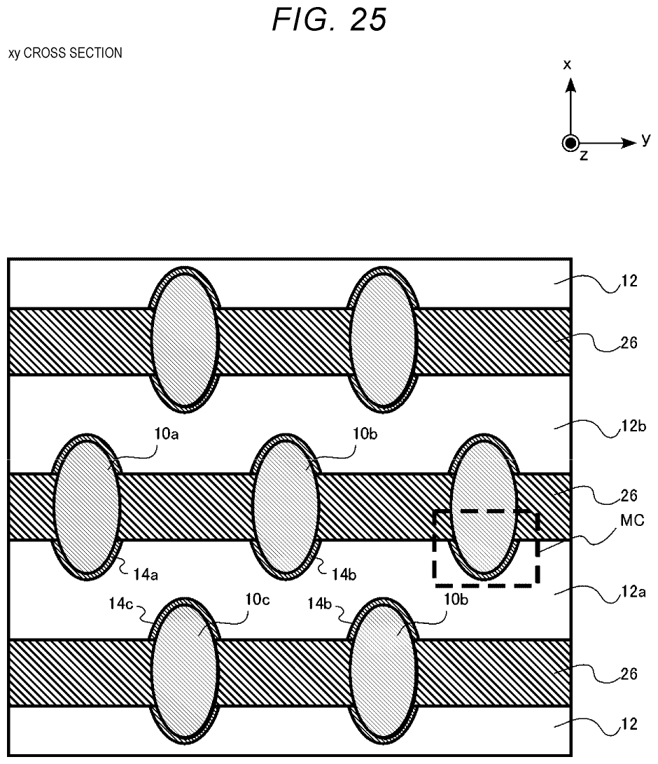

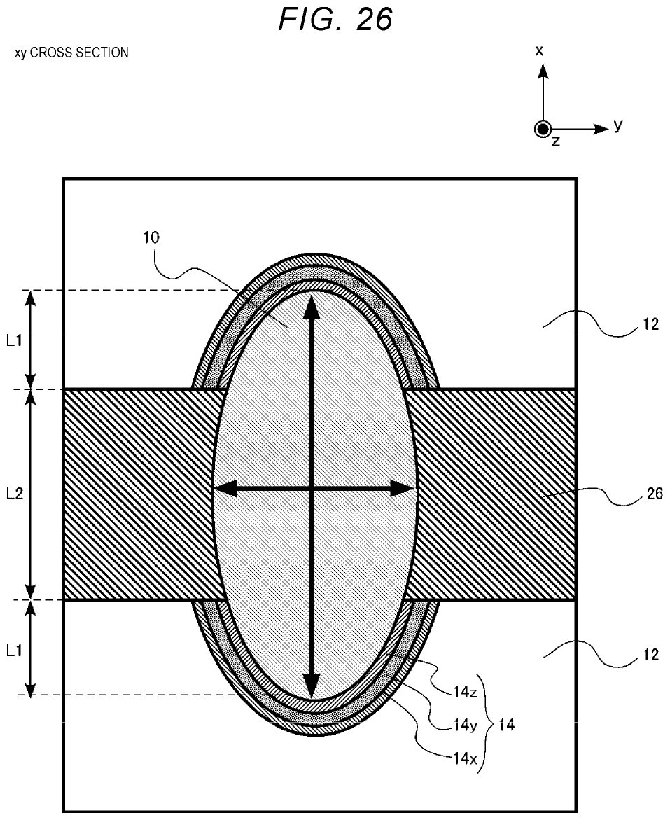

FIGS. 25 and 26 are schematic sectional views of the semiconductor memory device of the comparative example. FIGS. 25 and 26 are xy cross-sectional views of the memory cell array. FIG. 26 is a partially enlarged view of FIG. 25. FIGS. 25 and 26 are cross-sectional views including a semiconductor layer. FIGS. 25 and 26 are views corresponding to FIGS. 2 and 3 of the embodiment, respectively.

The three-dimensional NAND flash memory of the comparative example is different from the three-dimensional NAND flash memory of the embodiment in that the gate electrode layer 10 is arranged in a checkerboard pattern in the xy plane as shown in FIGS. 24 and 25. In addition, the three-dimensional NAND flash memory of the comparative example is different from the three-dimensional NAND flash memory of the embodiment in that the direction of the major axis of the gate electrode layer 10 is parallel to the x direction.

In the three-dimensional NAND flash memory of the comparative example, as in the embodiment, the first gate wiring layer 16a is electrically connected to the first gate electrode layer 10a, the second gate wiring layer 16b is electrically connected to the second gate electrode layer 10b, the third gate wiring layer 16c is electrically connected to the third gate electrode layer 10c, and the fourth gate wiring layer 16d is electrically connected to the fourth gate electrode layer 10d.

In the three-dimensional NAND flash memory of the comparative example, unlike the embodiment, as shown in FIG. 24, the first gate wiring layer 16a, the third gate wiring layer 16c, the second gate wiring layer 16b, and the fourth gate wiring layer 16d are arranged in this order in the y direction. In other words, positions of the first gate wiring layer 16a and the third gate wiring layer 16c in the y direction are interchanged as compared with the case of the embodiment.

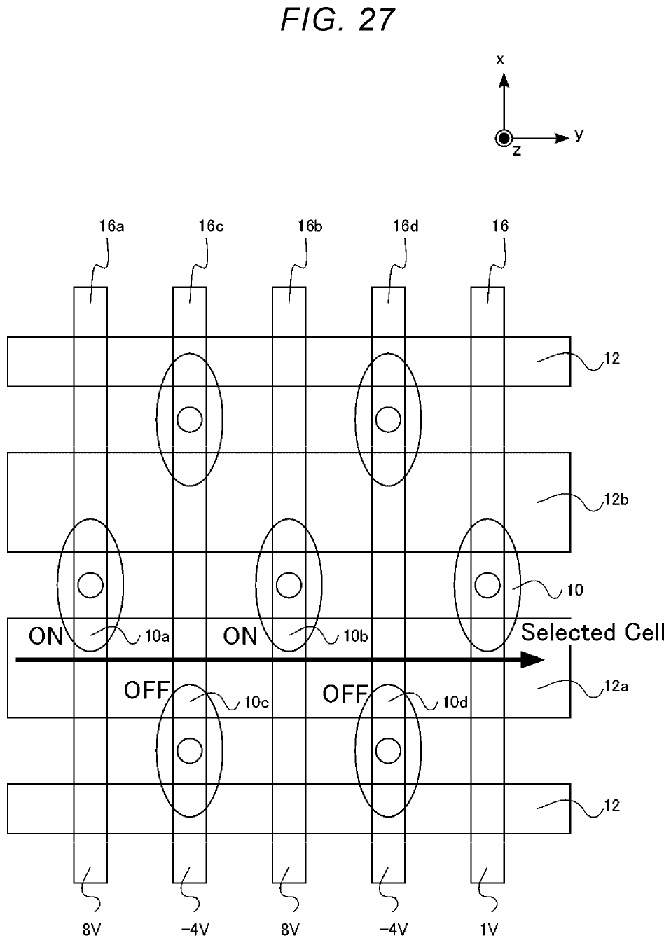

FIG. 27 is a view illustrating the operation and the effect of the semiconductor memory device of the embodiment. FIG. 27 is a view showing a voltage that is applied to the gate wiring layer 16 during a read operation of the three-dimensional NAND flash memory of the comparative example.

For example, a case where data stored in the shown selected cell is read will be considered. In this case, the plurality of memory cells MC each including the first gate electrode layer 10a, the second gate electrode layer 10b, the third gate electrode layer 10c, and the fourth gate electrode layer 10d and the first semiconductor layer 12a are non-selected cells.

For the first semiconductor layer 12a, when considering the first gate electrode layer 10a and the second gate electrode layer 10b provided on the same side as the gate electrode layer 10 of the selected cell in the x direction, it is necessary to form a channel in the opposing first semiconductor layer 12a to allow the flow of current. In other words, it is necessary to perform an on operation on the memory cell transistor controlled by the first gate electrode layer 10a and the second gate electrode layer 10b. Therefore, a read voltage is applied to the first gate wiring layer 16a electrically connected to the first gate electrode layer 10a and the second gate wiring layer 16b electrically connected to the second gate electrode layer 10b. The read voltage is, for example, 8 V.

On the other hand, for the first semiconductor layer 12a, when considering the third gate electrode layer 10c and the fourth gate electrode layer 10d provided on the side opposite to the gate electrode layer 10 of the selected cell in the x direction, it is necessary to prevent a current from flowing without forming a channel in the opposing first semiconductor layer 12a in order to avoid erroneous reading. In other words, it is necessary to perform an off operation on the memory cell transistor controlled by the third gate electrode layer 10c and the fourth gate electrode layer 10d. Therefore, an off voltage is applied to the third gate wiring layer 16c electrically connected to the third gate electrode layer 10c and the fourth gate wiring layer 16d electrically connected to the fourth gate electrode layer 10d. The off voltage is, for example, −4 V.

A determination voltage is applied to the gate wiring layer 16 connected to the gate electrode layer 10 of the selected cell. The determination voltage is, for example, 1 V.

In the three-dimensional NAND flash memory of the comparative example, as shown in FIG. 27, when focusing on one gate wiring layer 16 during the read operation of the memory cell MC, different voltages are applied to both the gate wiring layers 16 adjacent to each other. Therefore, the wiring capacitance of the gate wiring layer 16 may increase, and the read speed of the three-dimensional NAND flash memory may decrease.

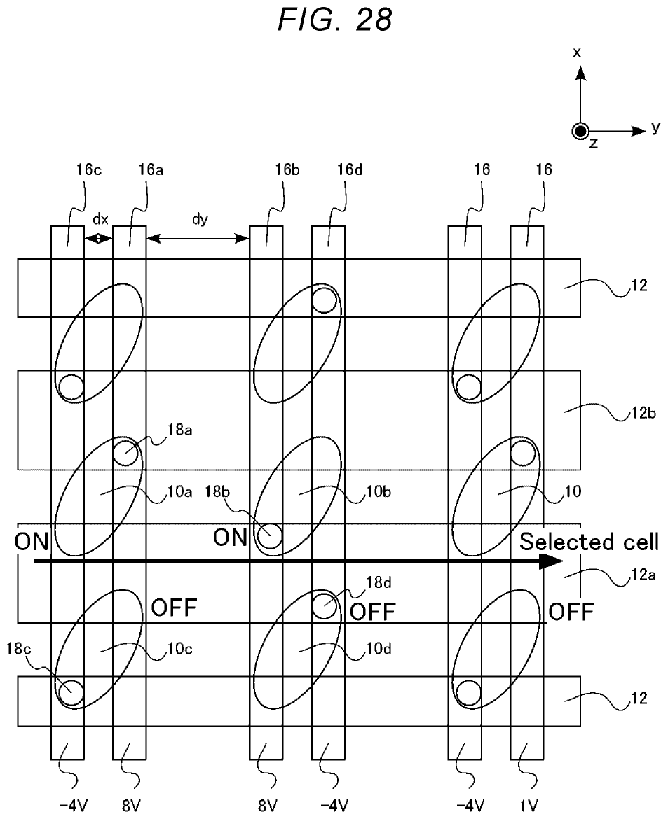

FIG. 28 is a view illustrating the operation and the effect of the semiconductor memory device of the embodiment. FIG. 28 is a view showing a voltage that is applied to the gate wiring layer 16 during the read operation of the three-dimensional NAND flash memory of embodiment.

For example, a case where data stored in the shown selected cell is read will be considered. In this case, the plurality of memory cells MC each including the first gate electrode layer 10a, the second gate electrode layer 10b, the third gate electrode layer 10c, and the fourth gate electrode layer 10d and the first semiconductor layer 12a are non-selected cells.

As in the case of the comparative example, for the first semiconductor layer 12a, when considering the first gate electrode layer 10a and the second gate electrode layer 10b provided on the same side as the gate electrode layer 10 of the selected cell in the x direction, it is necessary to form a channel in the opposing first semiconductor layer 12a to allow the flow of current. In other words, it is necessary to perform an on operation on the memory cell transistor controlled by the first gate electrode layer 10a and the second gate electrode layer 10b. Therefore, a read voltage is applied to the first gate wiring layer 16a electrically connected to the first gate electrode layer 10a and the second gate wiring layer 16b electrically connected to the second gate electrode layer 10b. The read voltage is, for example, 8 V.

On the other hand, as in the case of the comparative example, for the first semiconductor layer 12a, when considering the third gate electrode layer 10c and the fourth gate electrode layer 10d provided on the side opposite to the gate electrode layer 10 of the selected cell in the x direction, it is necessary to prevent a current from flowing without forming a channel in the opposing first semiconductor layer 12a in order to avoid erroneous reading. In other words, it is necessary to perform an off operation on the memory cell transistor controlled by the third gate electrode layer 10c and the fourth gate electrode layer 10d. Therefore, an off voltage is applied to the third gate wiring layer 16c electrically connected to the third gate electrode layer 10c and the fourth gate wiring layer 16d electrically connected to the fourth gate electrode layer 10d. The off voltage is, for example, −4 V.

A determination voltage is applied to the gate wiring layer 16 connected to the gate electrode layer 10 of the selected cell. The determination voltage is, for example, 1 V.

In the three-dimensional NAND flash memory of the embodiment, as shown in FIG. 28, when focusing on one gate wiring layer 16 during the read operation of the memory cell MC, a different voltage is applied to one of the gate wiring layers 16 adjacent to each other on both sides, and the same voltage is applied to the other. Therefore, the wiring capacitance of the gate wiring layer 16 is smaller than, for example, the wiring capacitance of the comparative example. Accordingly, the read speed of the three-dimensional NAND flash memory is improved.

In the three-dimensional NAND flash memory of the embodiment, from the viewpoint of reducing the wiring capacitance of the gate wiring layer 16, it is preferable that a distance between two gate wiring layers 16 to which different voltages are applied during the read operation is large.

For example, a distance in the y direction between the first gate wiring layer 16a and the third gate wiring layer 16c (dx in FIG. 28) is preferably ¼ or more, and more preferably ⅓ or more of the sum (dx+dy) of a distance in the y direction between the first gate wiring layer 16a and the third gate wiring layer 16c (dx in FIG. 28) and a distance in the y direction between the first gate wiring layer 16a and the second gate wiring layer 16b (dy in FIG. 28). By satisfying the above relationship, the wiring capacitance of the gate wiring layer 16 is reduced.

For example, it is possible to increase the distance dx by reducing the angle (e in FIG. 3) between the direction of the major axis of the gate electrode layer 10 and the y direction in the cross section perpendicular to the z direction. That is, by reducing the angle θ, for example, it is possible to increase a distance in the y direction between the first contact plug 18a and the third contact plug 18c. Therefore, it is possible to widen the distance dx between the first gate wiring layer 16a and the third gate wiring layer 16c.

In the three-dimensional NAND flash memory of the embodiment, it is possible to reduce the distance (L2 in FIG. 3) between the two semiconductor layers 12 adjacent to each other in the x direction as compared with the three-dimensional NAND flash memory of the comparative example.

For example, it is assumed that the shape of the gate electrode layer 10 in the xy cross section is elliptical having the same major axis and minor axis in the three-dimensional NAND flash memory of the comparative example and the three-dimensional NAND flash memory of the embodiment. Since the shapes of the gate electrode layers 10 in the xy cross section are the same, the cross-sectional areas of the gate electrode layers 10 are equal to each other. Since the cross-sectional areas of the gate electrode layer 10 are equal to each other, the electric resistance of the gate electrode layer 10 becomes constant.

In addition, for example, in order to align the transistor characteristics, it is assumed that the entering amount of the gate electrode layer 10 into the semiconductor layer 12 in the x direction (L1 in FIGS. 3 and L1 in FIG. 26) is the same between the three-dimensional NAND flash memory of the comparative example and the three-dimensional NAND flash memory of the embodiment.

Based on the above two assumptions, when the direction of the major axis of the elliptical gate electrode layer 10 of the embodiment as in the comparative example is inclined with respect to the x direction, the distance (L2 in FIG. 3) between the two semiconductor layers 12 adjacent to each other in the x direction of the embodiment is inevitably smaller than the distance (L2 in FIG. 26) between the two semiconductor layers 12 adjacent to each other in the x direction of the comparative example.

By reducing the distance (L2 in FIG. 3) between the two semiconductor layers 12 adjacent to each other in the x direction, it is possible to reduce the size of the memory cell in the x direction in the three-dimensional NAND flash memory of the embodiment. Accordingly, it is possible to increase the integration of the three-dimensional NAND flash memory.

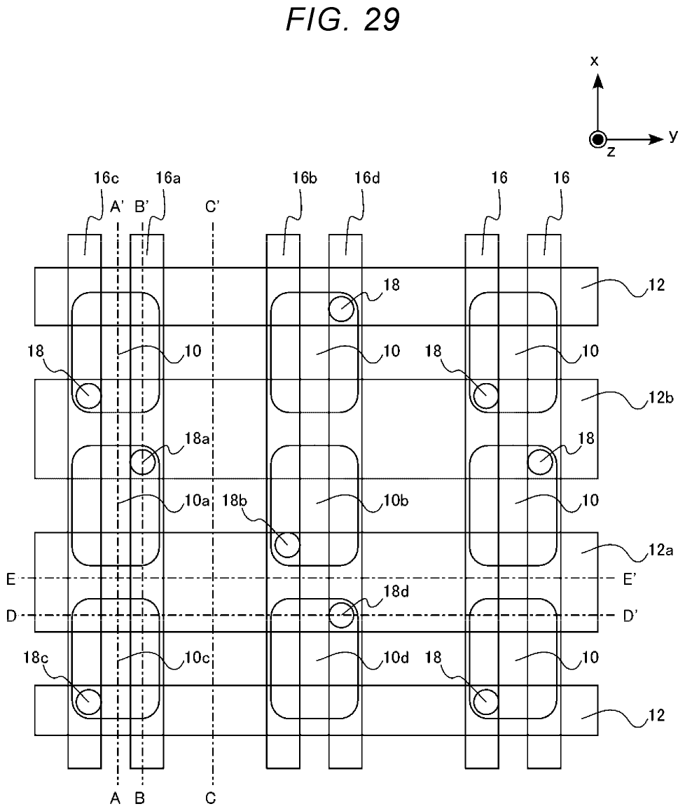

FIG. 29 is a pattern layout view of the semiconductor memory device of a modification example of the embodiment. FIG. 29 is a view corresponding to FIG. 1 of the embodiment.

The three-dimensional NAND flash memory of the modification example of the embodiment is different from the embodiment in that the gate electrode layer 10 has a rounded rectangle in the cross section perpendicular to the z direction.

As described above, according to the embodiment and the modification example, it is possible to provide a semiconductor memory device in which the wiring capacitance is reduced and the characteristics are improved.

In the embodiment and the modification example, a case where the shape of the gate electrode layer is elliptical or a rounded rectangular is described as an example in the cross section perpendicular to the z direction, but the shape of the gate electrode layer may be, for example, a circular shape, a square shape, a rounded square shape, a parallelogram, or a rounded parallelogram.

In the embodiment, the floating gate type memory cell in which the charge storage area is a conductor is described as an example, but as another embodiment, it is possible to use a charge trap type memory cell in which the charge storage area is an insulator.

In the embodiment, a case where the substrate is a semiconductor substrate is described as an example, but the substrate may be an insulating substrate. In addition, as another form, it is also possible to adopt a structure in which the substrate is not provided.

In the embodiment, a case where the number of gate electrode layers is 9 and the number of semiconductor layers stacked in the z direction is 3 is described as an example, but the number of gate electrode layers and the number of semiconductor layers are not limited to the above numbers.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first gate electrode layer extending in a first direction;
a second gate electrode layer extending in the first direction and disposed in a second direction intersecting the first direction with respect to the first gate electrode layer;
a third gate electrode layer extending in the first direction and disposed in a third direction intersecting the first direction and the second direction with respect to the first gate electrode layer;
a fourth gate electrode layer extending in the first direction, disposed in the second direction with respect to the third gate electrode layer, and disposed in the third direction with respect to the second gate electrode layer;
a first semiconductor layer extending in the second direction and disposed between the first gate electrode layer and the third gate electrode layer, and between the second gate electrode layer and the fourth gate electrode layer;
a first charge storage layer disposed between the first gate electrode layer and the first semiconductor layer;
a second charge storage layer disposed between the second gate electrode layer and the first semiconductor layer;
a third charge storage layer disposed between the third gate electrode layer and the first semiconductor layer;
a fourth charge storage layer disposed between the fourth gate electrode layer and the first semiconductor layer;
a first wiring layer extending in the third direction and being electrically connected to the first gate electrode layer;
a second wiring layer extending in the third direction, disposed in the second direction with respect to the first wiring layer, and being electrically connected to the second gate electrode layer;
a third wiring layer extending in the third direction and being electrically connected to the third gate electrode layer; and
a fourth wiring layer extending in the third direction, disposed in the second direction with respect to the third wiring layer, and being electrically connected to the fourth gate electrode layer,
wherein the first wiring layer is disposed between the third wiring layer and the fourth wiring layer, and
the second wiring layer disposed between the first wiring layer and the fourth wiring layer.

2. The semiconductor memory device according to claim 1, further comprising:
a substrate,
wherein the second direction is a direction along a surface of the substrate.

3. The semiconductor memory device according to claim 1,
wherein the first gate electrode layer has a major axis and a minor axis shorter than the major axis in a cross section perpendicular to the first direction.

4. The semiconductor memory device according to claim 3,
wherein the first gate electrode layer is elliptical in the cross section perpendicular to the first direction.

5. The semiconductor memory device according to claim 3,
wherein in the cross section perpendicular to the first direction, an angle between a direction of the major axis and the second direction is less than 90 degrees.

6. The semiconductor memory device according to claim 3,
wherein in the cross section perpendicular to the first direction, an angle between a direction of the major axis and the second direction is 45 degrees or more and 75 degrees or less.

7. The semiconductor memory device according to claim 1, further comprising:
a first connection portion provided between the first gate electrode layer and the first wiring layer, and connecting the first gate electrode layer and the first wiring layer;
a second connection portion disposed between the second gate electrode layer and the second wiring layer, and connecting the second gate electrode layer and the second wiring layer;
a third connection portion disposed between the third gate electrode layer and the third wiring layer, and connecting the third gate electrode layer and the third wiring layer; and
a fourth connection portion disposed between the fourth gate electrode layer and the fourth wiring layer, and connecting the fourth gate electrode layer and the fourth wiring layer,
wherein a direction in which the first connection portion and the second connection portion are connected intersects the second direction, and
a direction in which the third connection portion and the fourth connection portion are connected intersects the second direction.

8. The semiconductor memory device according to claim 7,
wherein the direction in which the first connection portion the second connection portion are connected intersects the direction in which the third connection portion and the fourth connection portion are connected.

9. The semiconductor memory device according to claim 1, further comprising:
a second semiconductor layer disposed in the third direction with respect to the first semiconductor layer, and extending in the second direction,
wherein the first gate electrode layer and the second gate electrode layer are disposed between the first semiconductor layer and the second semiconductor layer.

10. The semiconductor memory device according to claim 1, further comprising:
a third semiconductor layer disposed in the first direction with respect to the first semiconductor layer, extending in the second direction, disposed between the first gate electrode layer and the third gate electrode layer, and disposed between the second gate electrode layer and the fourth gate electrode layer.

11. The semiconductor memory device according to claim 1, wherein the gate electrodes include tungsten.

12. The semiconductor memory device according to claim 1, wherein the charge storage layers each include a tunnel insulating film, a charge storage area, and a block insulating film.

13. The semiconductor memory device according to claim 1, wherein the first semiconductor layer includes polycrystalline silicon.

14. The semiconductor memory device according to claim 1, wherein the wiring layers include at least one of tungsten, aluminum or copper.

15. The semiconductor memory device according to claim 1, wherein the substrate is formed of single crystal silicon.
